(19) United States
(12) Patent Application Publication
(10) Pub. No.: US 2013/0306133 A1
(43) Pub. Date: Nov. 21, 2013

(54) Solar Panel with Variable Heat Dissipation

(71) Applicants: Dirk Mueller, Aachen (DE); Carsten Wemhoener, Pfaeffikon (CH)

(72) Inventors: Dirk Mueller, Aachen (DE); Carsten Wemhoener, Pfaeffikon (CH)

(73) Assignee: RHEINISCH-WESTFAELISCH-TECHNISCHE, Aachen (DE)

(21) Appl. No.: 13/867,474

(22) Filed: Apr. 22, 2013

(30) Foreign Application Priority Data
Apr. 26, 2012 (DE) 102012206951.8

(51) Int. Cl. H01L 31/052

(52) U.S. Cl. CPC H01L 31/0521
USPC 136/246

(57) ABSTRACT

The techniques described herein relate to a solar collector with variable heat release and to a method for operating such solar collectors. The solar collector comprises a housing and an absorber arranged in the housing for purposes of releasing heat to a heat-transfer medium that flows at least partially through the housing, whereby the housing has at least one transparent cover to allow incident sunlight to pass through onto the absorber and to modify the heat release to the environment, whereby the cover is arranged in the housing in such a way that at least the mean distance between the cover and the absorber can be varied in order to adjust the heat release. Increasing the mean distance leads to a decrease of the heat release to the environment, while reducing the mean distance leads to an increase of the heat release to the environment.

### TECHNICAL FIELD OF THE INVENTION

The invention relates to a solar collector with variable heat release and to a method for operating such a solar collector.

### BACKGROUND

Solar collectors have now become a widespread system for heating up drinking water and for augmenting indoor heating systems. A thermal solar collector uses the absorbed solar energy to heat up a transfer medium (hot water), whereby thermal solar systems utilize virtually the entire radiation spectrum of sunlight with a relatively high degree of efficiency. Thermal solar collectors achieve relatively high degrees of efficiency in the utilization of sunlight, typically between 60% and 75%. The central component of the solar collector is the absorber (solar absorber), which converts the light energy of the sun into heat that is then released into a heat-transfer medium flowing through the absorber. By the heat-transfer medium, the heat is carried way from the collector and then immediately used or else stored. An example of solar collectors are so-called flat collectors having an appropriate external shape. The absorber in flat collectors has the shape of a plate so that, with the smallest possible volume, it exposes the largest possible surface area to the sun. Here, the heat-transfer medium in conventional systems flows through copper pipes onto which the collector panels are normally soldered for purposes of optimal heat transfer. When it comes to flat collectors, a distinction is made between covered and uncovered solar collectors.

Owing to their simple structure, uncovered solar collectors (usually plastic or metal collectors) are employed primarily to heat up water for swimming pools. In the case of uncovered solar collectors, air movements (wind) can directly attack the absorber, so that the heat losses due to convection can be high. This is why, as a rule, an uncovered solar collector does not reach particularly high temperatures in the absorber and in the heat-transfer medium, as result of which it can be made of inexpensive materials. German patent application DE 35 41 486 A1 discloses an uncovered solar collector having an absorber made of thermoplastic material in front of which a translucent shield can be reversibly mounted at a predefined distance for purposes of reducing heat losses. If the heat-transfer medium flows through an uncovered solar collector, for instance, during the night, the heat-transfer medium can be cooled through the release of heat to the colder environment by convection, by radiation and, in the case of a collector surface wetted with water, also by evaporation. Such a cooling function can also be utilized for cooling purposes.

If the objective is to reduce heat losses, then good thermal insulation of the absorber vis-á-vis the environment is necessary. For this purpose, predominantly flat collectors with a transparent glass cover are used, so-called covered solar collectors. The rays of incident sunlight that pass through the glass pane strike an absorber. When the sunlight rays strike, almost the entire spectral range of the light is absorbed. In order to reduce heat losses, the flat collector is thermally insulated on all sides, whereby the convective heat release towards the front is reduced by the glass pane. In the case of applications with higher temperature requirements, solar collectors with double-glazed glass covers or with a transparent interlayer consisting of a film under an outer glass cover are used as a so-called convection barrier. In the summer, when no heat is being consumed, such a covered solar collector can reach high temperatures of over 200° C. For this reason, covered solar collectors have to be made of appropriate thermally stable materials. Nevertheless, when no heat is being consumed (stagnation), the components continue to be highly stressed, which is why stagnation should be avoided to the greatest extent possible by continuing to consume heat.

As a result, however, the application possibilities of covered solar collectors are limited. German utility model DE 20 2005 005 631 U1 discloses a covered solar collector with which, in order to avoid overheating of the heat-transfer medium, a shading component having a partially shading film is additionally arranged in the housing of the solar collector. Whenever excessively high temperatures are reached in the housing of the solar collector, the shading film is moved by a roller system over the absorber in order to reduce the absorption of energy. This complicated temperature-controlled mechanical system makes the construction of the covered solar collector more complex, thus raising the production costs.

### SUMMARY

The techniques described herein generally describe a solar collector with variable heat release and to a method for operating such a solar collector.

Consequently, the objective of the present innovation is to put forward a solar collector that is simple as well as inexpensive to manufacture and that can also be used flexibly for different levels of heat consumption.

This objective is achieved by a solar collector comprising a housing and an absorber arranged in the housing for purposes of releasing heat to a heat-transfer medium that flows at least partially through the housing, whereby the housing has at least one transparent cover to allow incident sunlight to pass through onto the absorber and to modify the heat release to the environment, whereby the cover is arranged in the housing in such a way that at least the mean distance between the cover and the absorber can be varied in order to adjust the heat release.

In the embodiments described herein, the solar collector displays the behavior of a covered or an uncovered solar collector, depending on the distance selected between the absorber and the cover, as a result of which the solar collector is multifunctional. In the case of strong sunlight and a low demand for heat consumption, the distance between the absorber and the cover can be reduced so as to select the modality of an uncovered solar collector, which is thus cooler due to increased heat losses through the cover. At a smaller distance, the convection and radiation losses through the cover become greater owing to the smaller thermally insulating gas volume between the absorber and the cover. Consequently, it is possible to systematically prevent severe heating or even overheating of the housing and of the components in it. As a result, the materials that can be used for the production of these solar collectors do not have to be nearly as heat-resistant as those commonly used for covered solar collectors. If there is a great demand for heat, the distance between the absorber and the cover can be increased, as a result of which the above-mentioned heat losses are markedly reduced as a function of the distance, and consequently, the heat-transfer medium can be heated up to a greater extent. Aside from the cover, the solar collector does not need any other components in order to shade the absorber, as a result of which the production of the solar collector can be kept simple. The solar collector is thus easy and inexpensive to manufacture, in addition to which it can also be flexibly used for different heat consumption levels as needed. With this solar collector, for instance, the following modes of operation can be implemented by correspondingly adjusting the distance between the absorber and the cover:
if there is a demand for heat and if sunlight is present, the mode of operation as a covered solar collector (large distance) with reduced heat losses to the environment is advantageous (heating operation);
in contrast, if there is no demand for heat and if strong sunlight is present, the operating temperature of the solar collector can be reduced by increasing the heat losses to the environment (small distance) and a high stagnation temperature that would severely stress the components of the solar collector can be avoided (stagnation operation);
in only a small amount of sunlight is present, heat can be extracted from the ambient air or from rain, dew, frost, ice or snow accumulated on the surface of the collector by selecting operation as an uncovered solar collector (small distance) at ambient temperature;
for nighttime operation as an uncovered solar collector (small distance), heat can be released from the heat-transfer medium to the ambient air through convection, radiation, and if the cover is wetted with water, through evaporation, so that the heat-transfer medium is cooled (cooling operation).

The distance between the cover and the absorber can be set or varied in any way that is deemed suitable by the person skilled in the art, for example, by a mechanically or electrically driven device for varying or setting a certain distance. In one embodiment, the solar collector comprises an appropriate control unit for selecting the mode of operation (e.g. heating operation, stagnation operation or cooling operation) and for setting the distance between the absorber and the cover that is practical for this purpose. This control unit can be equipped with appropriate sensors, such as a photodiode for determining the incident sunlight, one or more temperature sensors for determining the temperature of the heat-transfer medium and/or the temperature inside and/or outside of the housing of the solar collector, and/or a clock for ascertaining the time of day. The control unit can be installed inside or outside of the housing of the solar collector, whereby the control unit is suitably connected to the setting component for setting the distance between the absorber and the cover so as to be able to actuate them.

The term “housing” refers to the components of the solar collector that surround the absorber and to the lines for conveying the heat-transfer medium inside the solar collector. The cover is a component of the housing. The term “absorber”, in contrast, refers to the component that absorbs the incident sunlight through the transparent cover at least partially, and in some embodiments virtually completely. This absorption heats up the absorber, which can then transfer this heat to the heat-transfer medium. Typical absorbers usually consist of one or more absorbing plates made of aluminum or copper. Optionally assisted by a selective coating, this absorber heats up under exposure to sunlight. In order to obtain the best possible absorption and utilization of the sunlight on the absorber, it is desirable to have selective properties of the highest possible absorptance α in the short wavelength range from 200 nm to 800 nm and the lowest possible emissivity ε in the long wavelength range >1 μm.

In order for heat to be conducted from the absorber to the heat-transfer medium, the absorber is, for example, permanently joined to the copper or aluminum pipes that convey the heat-transfer medium (lines of the heat-transfer medium). The heat output that has been transferred to the heat-transfer medium is then transported by these lines via the heat-transfer medium away from the solar collector and to a consumer or to a heat accumulator. In other embodiments, the solar collector has an open circulation system for the heat-transfer medium, whereby the heat-transfer medium that is to be heated, for instance, water, flows directly through the absorber. In regions at great risk of frost, however, separate circulation systems are normally employed to transport the heat-transfer medium. A substance that lowers the freezing point, for example, propylene glycol, can be admixed to the heat-transfer medium that is circulating in the closed circulation system, also referred to as the primary circulation system. The conceivable embodiments for supplying the heat-transfer medium to the solar collector and subsequently draining it out of the solar collector can be selected as deemed suitable by the person skilled in the art. In any case, it is necessary to ensure good heat transfer from the absorber to the heat-transfer medium that flows at least partially through the solar collector, whereby here the heat-transfer medium can be conveyed in lines in the absorber or on the absorber while making heat-conductive contact along the absorber, or else it can flow directly through the absorber or along it. Examples of heat-transfer media that can be used are liquids such as water, or gases such as air.

The term “transparent cover” here designates the side of the solar collector through which the sunlight passes to subsequently strike the absorber and be absorbed there. This is the side facing the sun and will be referred to below as the top or front. This top is arranged at an angle to the sunlight that allows the largest possible incidence of sunlight onto the absorber. Ideally, the incident sunlight strikes the cover perpendicularly. Therefore, the cover to be at least partially transparent to sunlight. In embodiments, the cover exhibits a high transmittance over the broadest possible wavelength range of the solar spectrum. Particularly well-suited are covers having a transmittance τ≧0.9, especially if this high transmission lies in the short wavelength range of 200 nm to 800 nm. In order to employ the solar collector for cooling applications, the cover should have a high emissivity ε in the long wavelength range, especially in the wavelength range of the atmospheric window ranging from 8 μm to 13 μm. The term “atmospheric window” refers here to the wavelength interval for which the atmosphere of the Earth is largely permeable (transparent).

The phrase “heat release to the environment” refers to the heat losses of the solar collector. The release of heat to the heat-transfer medium is not encompassed by the phrase “heat release to the environment” because this heat transfer is not desired and thus does not constitute a loss. The heat release to the environment designates the heat losses from the housing of the solar collector, whereby these losses can occur towards the rear, the front or the side surfaces. Therefore, the term “environment” stands for the surroundings outside of the solar collector, but not to the heat-transfer medium and its conveyance in pipes of the solar collector.

The distance between the absorber and the cover can be varied locally depending on the geometrical shape of the absorber and/or of the cover, even if the cover and the absorber are in a fixed position. The term “mean distance” here relates to the average distance from the inside of the cover to the surface of the absorber facing the cover.

The solar collector can have any desired external shape. If the solar collector is configured, for example, as a flat collector, the solar collector comprises an absorber in the form of a plate so that, with the smallest possible volume, it exposes the largest possible surface area to the sun. Accordingly, the cover is also configured as a surface parallel to the absorber. In other embodiments, the solar collector can be configured as a so-called tube collector, whereby the tubes used as absorbers are those in which the tube containing the heat-transfer medium itself serves as the absorber. Here, the cover can be configured as a curved or flat surface located above the absorber. Other alternative solar collector forms selected by the person skilled in the art are likewise encompassed by this disclosure.

In one embodiment, the cover comprises at least one plastic film or plastic plate or at least one glass pane. In this context, the cover can be made completely of the above-mentioned materials, or else the materials, as the transparent part of the cover, are held in a suitable frame that constitutes another component of the cover and that is suitably joined to the rest of the housing. Glass panes have a very high transmittance for radiation at wavelengths within the range of the solar spectrum, for instance, τ≈0.9 for extra-white glass or τ≈0.95 for extra-white glass with an anti-reflective coating. In parallel to this, glass panes have a high emissivity ε in the long wavelength range of approximately 0.9. The same applies to covers made of plastic plates or plastic films. In embodiments, the plastic plates or plastic films are made of fluoropolymers. In embodiments, covers made of fluoropolymer ethylene tetrafluoroethylene (ETFE) or perfluoroethylene propylene (FEP) films are used in the solar collector. Perfluoroethylene propylene (FEP) copolymer is a fluorinated copolymer consisting of various fluorinated monomers and optionally ethylene or propylene. The higher the content of fluorine, the better the temperature resistance. Ethylene tetrafluoroethylene (ETFE) is likewise a fluorinated copolymer, consisting of the monomers tetrafluoroethylene and ethylene. Such a film displays a shortwave transmittance τ≈0.95, whereby, in comparison to glass, parts of the UV spectrum are also transmitted, which increases the amount of energy from sunlight that is made available to the absorber. The long-wave emissivity of the film lies in the range of ε≈0.65, which is still high enough for the solar collector to be able to operate in the cooling mode. Films made of this plastic have a low intrinsic weight and can be manufactured, for example, with a thickness ranging from 50 μm to 250 μm. Moreover, such a film is temperature-resistant to over 200° C., flame-retardant, self-cleaning, weathering-resistant, chemical-resistant and UV-resistant. Furthermore, its tear-resistance, tear propagation-resistance and puncture-resistance are high. The use of films and plastics in solar collectors, especially as covers, yields lighter solar collector constructions at reduced costs.

In one embodiment, the solar collector also comprises a setting component to vary the distance between the absorber and the cover. This setting component is mechanically and/or electrically connected to the cover in a suitable manner so that the distance between the absorber and the cover can be varied. For instance, the cover runs in rails arranged vertically to the surface of the cover and it can be moved along the rails by a mechanical coupling to a motor, which increases or decreases the distance from the absorber. The setting component here is, for example, the motor or the motor control unit. In an embodiment, the solar collector also comprises a photovoltaic element that is at least configured to supply the setting component with electricity. In this case, the solar collector is configured as a hybrid solar collector that utilizes the incident solar energy both thermally and electrically. The photovoltaic element can be installed by a person skilled in the art at any suitable place in the solar collector. The photovoltaic element is configured at least in such a way that the electric energy generated from the solar energy is sufficient to move the cover. If applicable, the photovoltaic element comprises a storage unit for the electric energy, for instance, a battery, so that the distance between the cover and the absorber can be varied during night operation as well. In another embodiment, the absorber comprises the photovoltaic element and a device at the rear to transfer heat to the heat-transfer medium; in this context, the absorber is configured completely as a photovoltaic element with a device at the rear for thermal insulation. In this embodiment, the absorber itself is configured as a hybrid absorber, in other words, the entire surface area of the absorber is designed as a photovoltaic element with a device at the rear that carries away the heat (also referred to as a photovoltaic-thermal (PV/T) collector). This avoids space-related situations in the housing of the solar collector that might restrict the installation of the device used to vary the distance of the cover.

In one embodiment, the setting component comprises a mechanical drive, whereby the cover is mounted on the housing in such a way that it can be moved relative to the absorber, and the mechanical drive and the mounting of the cover are configured in such a way that the distance between the absorber and the cover can be varied by the mechanical drive. For instance, the cover runs in rails on the inside of the housing and is connected to the mechanical drive by one or more cable controls or one or more chains that connect the mechanical drive to the cover via one or more return pulleys. By mechanically pulling on the cables or chains, the cover can be moved upwards along the rails, thus increasing the distance between the cover and the absorber. In the opposite mode of operation of the motor, the distance can be correspondingly reduced or the cover can be brought into contact with the absorber. As an alternative, the cover can also be secured in a frame that can be moved along the housing that surrounds it. This frame can also be mounted, for example, on a telescopic mount, for instance, telescopic feet or columns, on the inside of the rear wall of the solar collector. Via the mechanical driven element, the length of the telescopic mount is changed, which then changes the distance of the frame to the rear wall and thus the distance of the cover relative to the absorber. Within the scope of the techniques described herein, a person skilled in the art can also employ alternative approaches for moving the cover relative to the absorber. These embodiments can be used for flexible as well as rigid covers. The distance can be varied or set very precisely and reproducibly by mounting the cover on a guided support. This type of distance variation is very well-suited for a precise regulation of the heat release by the solar collector.

In another embodiment, the cover comprises, aside from at least one plastic film, also a readjustment mechanism which is suitable for accommodating thermal material expansions and in which the plastic film is fastened. In this manner, even when thin films are employed as covers, it is achieved that the distance between the absorber and the cover that is set by the setting component is kept constant, even in case of temperature fluctuations (internal or external). This allows a precise regulation of the heat release employing the above-mentioned technique of distance variation, even when the transparent cover is in the form of a film.

In another alternative embodiment, the cover is an essentially air-tight, mechanically flexible cover connected to the housing. The housing is filled with gas, at least between the cover and the absorber, and the setting component comprises a device for variably selecting the gas pressure in the housing. The term “essentially” refers to a leakage rate that is so low that the pressure selected in the housing does not change perceptibly to an external observer over a long period of time (one or more hours) without any additional gas being fed in. In the case of a cover that is mounted so as to be mechanically movable, for instance, in vertical rails, the distance can be changed by varying the gas pressure, even for rigid covers. In this embodiment, the distance is increased in that an elevated gas pressure presses a rigid cover upwards (away from the absorber). Conversely, by reducing the gas pressure, the same cover can slide again along the rails in the direction of the absorber by virtue of the force of gravity or of the external air pressure. However, the mechanically movable mounting of the cover has to be configured to be gas-tight since otherwise, it would not be possible to build up pressure inside the solar collector. In an embodiment, the cover that is joined to the housing by an air-tight connection is mechanically flexible. This avoids mechanical constructions of the type described above. An elevated gas pressure in the housing causes an air-tight and yet flexible cover to bulge upwards (away from the absorber). This does not change the distance from the absorber at the mechanically fixed edges of the cover; the distance is at its largest in the middle of the cover (largest distance from the mechanically fixed edge). In this manner, the mean distance from the cover to the absorber is increased by raising the gas pressure. The mean distance here is calculated from the mean value of the distances of all points on the cover with respect to the absorber. Conversely, the outwards bulging of said cover is reduced due to the external air pressure when the gas pressure is reduced. If negative pressure were to prevail in the housing of the solar collector, the mechanically flexible cover would even bulge in the direction of the absorber due to the external air pressure. Depending on the geometrical shape of the absorber, cover, housing and attachment of the cover on the housing, the cover comes into contact with the absorber at a different pressure in the solar collector. Optionally, no contact is established with the absorber if the construction is designed accordingly. A device for setting the gas pressure comprises, for example, a gas cylinder connected to the solar collector at the appropriate excess pressure and a valve that is between the gas cylinder and the interior of the housing and that is regulated by the device. In another embodiment, in order for the pressure to be relieved, the housing can have a second gas outlet valve regulated by the device, said valve being closed when pressure is being built up. In this manner, with a time-limited gas feed, a constant pressure between the cover and the absorber can be maintained over a prolonged period of time. In another embodiment, the device comprises a fan with a suitable gas feed. This permits a pressure build-up in the housing even without a gas reservoir that is under negative pressure. This embodiment is thus structurally easier to implement. However, the fan here has to stay in operation for as long as the bulge in the cover has to be maintained.

The embodiments for rigid or flexible covers can also comprise multiple covers, either by forming several gas-filled, including air-filled chambers that are made of several sheets of film material laid on top of each other and that can be selectively filled up or emptied, for instance, via parallel separate gas-feed channels leading to the individual chambers, or else through frame elements that are nested, that can move relative to each other and that comprise several covers.

In one embodiment, the heat-transfer medium flows through the absorber, which is made of plastic or of a coated material, for instance, aluminum or copper, or else made partially or entirely of a photovoltaic element. The absorber made of plastic is simple and inexpensive to manufacture. In an embodiment, the plastic material is ethylene propylene diene monomer (EPDM) rubber. EPDM is a terpolymer elastomer and belongs to the statistic copolymers having a saturated polymer backbone. It has high elasticity and good chemical resistance. EPDM is a commonly used material for hoses that carry steam or hot water. EPDM rubber contains 45% to 75% by weight of ethylene. Polymers with a low ethylene content (45% to 55% by weight) have the best low-temperature flexibility. Terpolymers containing more than 65% by weight of ethylene display a high tear resistance already in the non-cross-linked state.

The coating of appropriately coated absorbers is intended to improve the absorption and emission properties of the absorber. This is why the absorber in some embodiments is colored with black coatings. Other coatings such as, for instance, Eta plus, Tinox or Sunselect usually give the absorber a bluish-shimmering color. Regarding the coatings of the absorber, a distinction is made between selective and non-selective coatings. The latter have absorption and emission properties that are similar within a broad wavelength range of sunlight. In an embodiment, the absorber is selectively coated. Selective coatings have highly differing absorption and emission properties in different wavelength ranges. The term “selective” here refers to layers that absorb the shortwave solar energy coming from the outside particularly well (absorption) and that do not release (emission) the longer-wave heat energy of the absorber very well. Advantageous selectively coated absorbers have a very low emissivity ε>1 μm in the long wavelength range and are therefore particularly suitable for the effective utilization of the incident solar energy. This coating is also suitable for the cooling operation by the solar collector since the cover for this mode of operation can be brought into mechanical contact with the absorber by changing the distance appropriately. Since only the emission properties of the uppermost layer, in other words, here the top of the cover, are determined, the cover that is in contact with the absorber, for instance, a plastic film, allows a good emission to be attained in spite of the selective coating of the absorber. The prerequisite for this is good thermal contact between the absorber and the cover that is in contact with it. In another mode of operation at the desired strong level of heat release from the solar collector to the heat-transfer medium, the selective coating of the absorber when the cover is completely at a distance from the absorber (for example, in the case of a large distance between the absorber and the cover) leads to the desired strong absorption of solar energy by the absorber while concurrently minimizing the dissipation losses from the absorber in the longer wavelength range of the heat radiation.

In another embodiment, the housing comprises thermal insulation at the rear. This prevents the undesired release of heat to the environment. In an embodiment, this thermal insulation at the rear comprises thermal insulation material or a wall at the rear, such as a film or plate, and a gas-filled gap between the wall and the rear of the absorber. Consequently, a simple geometrical shape of the gap allows the desired degree of thermal insulation to be set. In an embodiment, the housing comprises a pressure setting component for setting the gas pressure in the gas-filled gap or else a component for enlarging the gap between the wall and the rear of the absorber. In this manner, the thermal insulation can be flexibly set at the rear during the operation of the solar collector. In this context, the gas pressure, such as the air pressure, can be set with the pressure setting component for setting the gas pressure in order to vary the distance between the cover and the absorber. In one embodiment, the setting component is also employed to set the gas pressure in the gap between the rear of the wall and the absorber. For this purpose, appropriate gas channels lead from the setting component to this gap.

The techniques described herein also relate to a method for operating a solar collector as described herein, comprising a housing with a transparent cover and an absorber arranged in the housing, in order to release heat to a heat-transfer medium that flows at least partially through the housing, encompassing the following steps:
increasing at least the mean distance between the absorber and the transparent cover in order to decrease the heat release to the environment as needed; and
reducing at least the mean distance between the absorber and the transparent cover in order to increase the heat release to the environment as needed.

In addition to the above-mentioned advantages, a reduction of the distance between the cover and the absorber allows heat to be extracted from the ambient air or from condensation, rain, frost, snow or ice accumulated on the surface of the collector. Owing to the good thermal contact between the absorber and the cover brought about by reducing the distance, it is also easier to remove condensation, rain, frost, snow or ice from the cover. Therefore, additional cleaning procedures for the solar collector can be reduced or completely eliminated. This can be very user-friendly and avoid additional work, particularly in the case of large and/or hard-to-access solar collector surfaces. Reducing the distance can also lower the stagnation temperature of the solar collector. The solar collector, especially the cover, is better equipped to withstand snow loads and stress caused by hail when the distance between the cover and the absorber is reduced, especially when contact is established between the cover and the absorber.

In one embodiment, the method encompasses the additional step of minimizing the distance between the absorber and the transparent cover in order to release heat from the housing of the solar collector into the environment.

In one embodiment, the method also encompasses the steps of increasing or decreasing the distance by appropriately mechanically moving the cover by a mechanical drive or else by changing the gas pressure at least between the cover and the absorber by an appropriate device, such as a fan.

In one embodiment, the method also encompasses the step of setting the degree of thermal insulation at the rear, which consists of a wall arranged at the rear, such as a film or plate, and of a gas-filled gap located between the wall and the rear of the absorber, by changing gas pressure in the gap employing component arranged at least partially in the housing, or by enlarging or reducing the gap between the wall and the rear of the absorber.

### BRIEF DESCRIPTION OF THE DRAWINGS

These and other aspects of the present innovation are presented in detail in the drawings.

FIG. 1 illustrates an embodiment of a solar collector, with a rigid cover.

FIG. 2 illustrates an embodiment of a solar collector, with a flexible cover.

FIG. 3 illustrates various embodiments of solar collectors, with a rigid cover: (a) raised cover and non-adjustable thermal insulation at the rear, (b) cover that makes contact and non-adjustable thermal insulation at the rear, (c) raised cover and thermal insulation at the rear at a high setting, (d) cover that makes contact and thermal insulation at the rear at a low setting, (e) multiple cover created by raised covers and non-adjustable thermal insulation at the rear, and (f) multiple cover created by a cover that makes contact and that is raised, and non-adjustable thermal insulation at the rear.

FIG. 4 illustrates various embodiments of solar collectors, with a flexible cover: (a) raised cover and non-adjustable thermal insulation at the rear, (b) cover that makes contact and non-adjustable thermal insulation at the rear, (c) raised cover and thermal insulation at the rear at a high setting, (d) cover that makes contact and thermal insulation at the rear at a low setting, (e) multiple cover created by raised covers and non-adjustable thermal insulation at the rear, and (f) multiple cover created by a cover that makes contact and that is raised, and non-adjustable thermal insulation at the rear.

FIG. 5 illustrates a method for operating a solar collector.

### DETAILED DESCRIPTION OF EMBODIMENTS

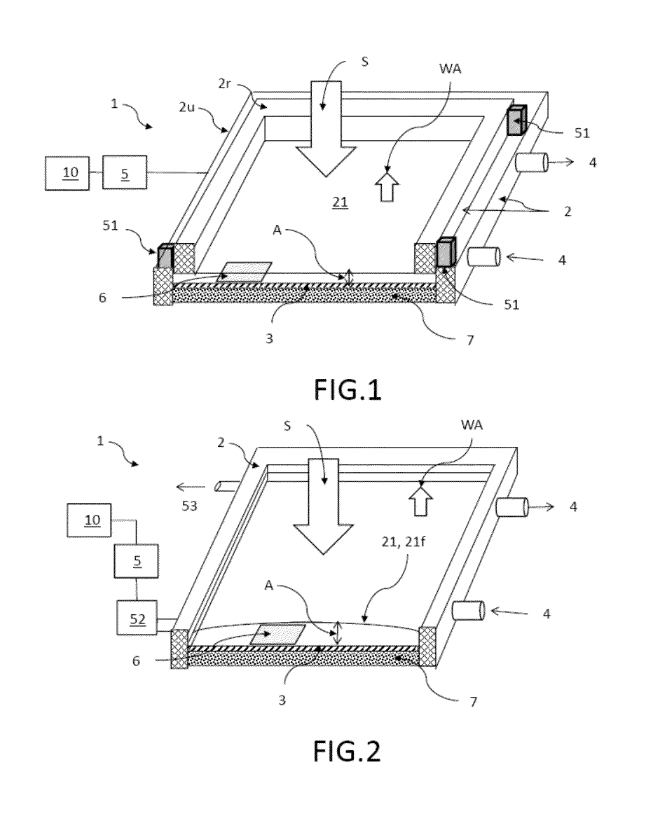

FIG. 1 illustrates an embodiment of a solar collector 1, in the form of a flat collector having a housing 2 and an absorber 3 that is arranged in the housing 2 and that is shown here as a layer with diagonal lines. This absorber 3 extends parallel to the cover 21, which is arranged between the frame 2r as part of the housing 2. The heat absorbed from the incident sunlight S is transferred by the absorber 3 via a heat-conductive contact to a heat-transfer medium 4 that flows at least partially through the housing 2. The layout of the heat-transfer medium 4 in the solar collector 1, especially in or around the absorber 3, is not shown in detail since the layout of the heat-transfer medium 4 for the solar collector 1 can be selected as deemed suitable by the person skilled in the art. The layout of the heat-transfer medium 4 here is only indicated by the two inlet and outlet pipes with the appertaining arrows at the side of the housing 2. The housing 2 has a transparent cover 21 so that the incident sunlight S can strike the absorber 3. For purposes of changing the heat release WA to the environment, the cover 21 is arranged in the housing 2 in such a way that at least the mean distance A between the cover 21 and the absorber 3 can be varied in order to set the heat release WA. The heat release WA drawn here (arrow) is depicted for heat release through the cover. This heat release WA is influenced by the change in the distance from the cover 21 to the absorber 2. However, the solar collector 1 can also lose heat via other parts of the housing 2, for instance, via the side surfaces of the solar collector 1 or via its rear. The rear is the side that is opposite from the side (cover 21) through which the incident sunlight S enters. In order to minimize or prevent heat release via the rear, the solar collector 1 in the embodiment shown here comprises heat-insulation 7 at the rear, which can be selected as deemed suitable by the person skilled in the art. The cover 21 in this embodiment consists of a plastic plate, such as fluoropolymer, or of a glass pane, which is affixed to a frame 2r belonging to the housing 2. The frame 2r is moved by several mechanical drives 51 arranged on the frame 2r, for instance, by gearwheels that engage with corresponding toothed racks (not shown explicitly here) located on the frame 2r. Since the cover 21 is held in the frame 2r, the cover moves relative to the absorber 3 due to the movement of the frame 2r, so that the distance A between the absorber 3 and the cover 21 can be varied by the mechanical drives 51. The frame 2r of the housing 2 is installed in the housing 2u that surrounds it, so as to allow a vertical distance change A. The arrangement of the drives 51 shown here is only given by way of an example. Within the scope of the techniques described herein, a person skilled in the art can also select other arrangements for the mechanical drives 51 and/or a different number of mechanical drives 51. The mechanical drives 51 are part of a setting component 5 that serves to vary the distance A between the absorber 3 and the cover 21. The setting component 5 is regulated by a control unit 10 for selecting the mode of operation since the selection of the mode of operation can cause a change in the distance A. Depending on the mode of operation chosen, the mechanical drives 51 are actuated by the setting component 5 that controls them in such a way that the desired distance A is set. For purposes of providing the mechanical drives 51 with power, the solar collector 1 also comprises a photovoltaic element 6 that is designed to provide power to the setting component 5 and thus also to the mechanical drives 51. In this embodiment, the photovoltaic element 6 is arranged on the absorber 3. In other embodiments, the photovoltaic element 6 can also be located in other places in or on the housing 2 or else outside of the housing 2, provided that it is electrically connected at least to the setting component 5.

FIG. 2 illustrates another embodiment of a solar collector 1, in the form of a flat collector having a housing 2 and an absorber 3 that is arranged in the housing 2 and that is shown here as a layer with diagonal lines, as well as having a cover 21 whose mean distance A to the absorber 3 can be varied. In order to illustrate the differences between the two embodiments according to FIGS. 1 and 2, only the distinguishing features will be elucidated in detail here. The explanations given regarding the absorber 3, the heat-transfer medium 4 and its layout through the solar collector 1, the thermal insulation 7 at the rear, the photovoltaic element 6 and the control unit 10 apply analogously to FIG. 1. Here, the housing 2 has a flexible cover 21f as the cover 21 configured, for example, in the form of a plastic film 21f, such as fluoropolymer and connected to the housing 2 so as to be air-tight. In this context, the housing is filled with gas, at least between the cover 21f and the absorber 3. Changing the gas pressure between the cover 21f and the absorber 3 causes the cover 21f to bulge outwards (excess pressure relative to the air pressure on the outside) or else inwards (negative pressure with respect to the air pressure on the outside). When the bulge is changed by varying the gas pressure, the mean distance A between the flexible cover 21f and the absorber 3 can be set or varied. Towards this end, the setting component 5 actuates a device 52 to variably set the gas pressure in the housing 2. Here, in contrast to the embodiment shown in FIG. 1, the housing 2 can comprise a single rigid frame in which the flexible cover 21f is secured, for instance, it is clamped into the housing 2 that surrounds it, or else it is glued or welded to the housing 2 that surrounds it. The device 52 can be, for example, a gas cylinder from which gas at an excess pressure is admitted into the housing 2. The admission is controlled by the setting component 5 by, for instance, a regulatable valve (not shown here). FIG. 2 also shows a gas outlet 53 for reducing the gas pressure in the housing 2 between the cover 21f and the absorber 3. This gas outlet 53 likewise has, for example, a regulatable valve that is controlled by the setting component 5. In order for the desired distance to be set, a control scheme, for instance, is stored in the setting component 5, and this is where the gas pressures that correspond to the desired distances are stored, for example, in the form of a data table that can be accessed by a control program of the setting component 5.

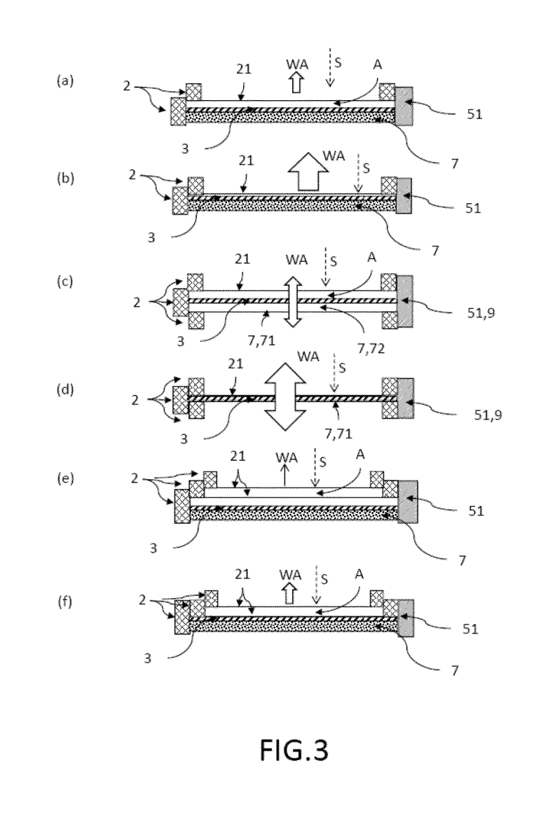

FIG. 3 shows various embodiments of solar collectors 1, in the form of flat collectors that each have a rigid cover 2, for instance, a plastic plate or a glass pane:
(a) This embodiment corresponds to the solar collector 1 already shown in FIG. 1, with the cover 21 raised and non-adjustable thermal insulation 7 at the rear. Here, the heat release WA through the cover 21 is low due to the large distance A that has been set.
(b) This embodiment corresponds to the solar collector 1 already shown in FIG. 1, with the cover that makes contact 21 and non-adjustable thermal insulation 7 at the rear. Here, the heat release WA through the cover 21 that is in contact is at its maximum due to the minimum distance A from the absorber that has been set (A=0 when the cover is in contact). (c) This is another embodiment of a solar collector 1. The side facing the incident sunlight S corresponds to the situation shown in FIG. 3(a). Here, however, the thermal insulation at the rear comprises a wall 71 at the rear, such as a film or plate, and a gas-filled gap 72 between the wall 71 and the rear of the absorber 3. Setting component 9 arranged on the housing 2 were employed to set a large gap 72 between the wall 71 and the rear of the absorber 3. As a result, the heat release WA is low, both through the cover 21 as well as through the rear (wall) 71. In some embodiments, the setting component 9 can be configured with mechanical drives 51 and arranged so as to be separate from the setting component 5. Here, in contrast, the mechanical drive 51 is also responsible for setting the width of the gap 72. The mechanical arrangement at the rear of the absorber 3 corresponds to the arrangement for moving the cover 21 on the side facing the incident sunlight S.
(d) This is the embodiment like in FIG. 3(c), whereby now the distances A between the cover 21 and the absorber 3 as well as between the wall 71 and the absorber 3 are minimized As a result, the heat release WA through the cover 21 as well as through the rear (wall) 71 is at its maximum. (e) This shows another embodiment of a solar collector 1, with a multiple cover 21, configured here as a two-part cover 21. Here, the heat release WA through the two raised covers 21 is even much lower than, for example, in FIG. 3(a), since the two distances A have been set to be large. Here, the thermal insulation 7 at the rear is not adjustable. The heat release through this thermal insulation 7 at the rear depends on its quality. (f) This embodiment, as already shown in FIG. 3(e), shows the inner cover 21 in contact with the absorber 3, so that the same properties are obtained for the heat release WA as in FIG. 3(a).

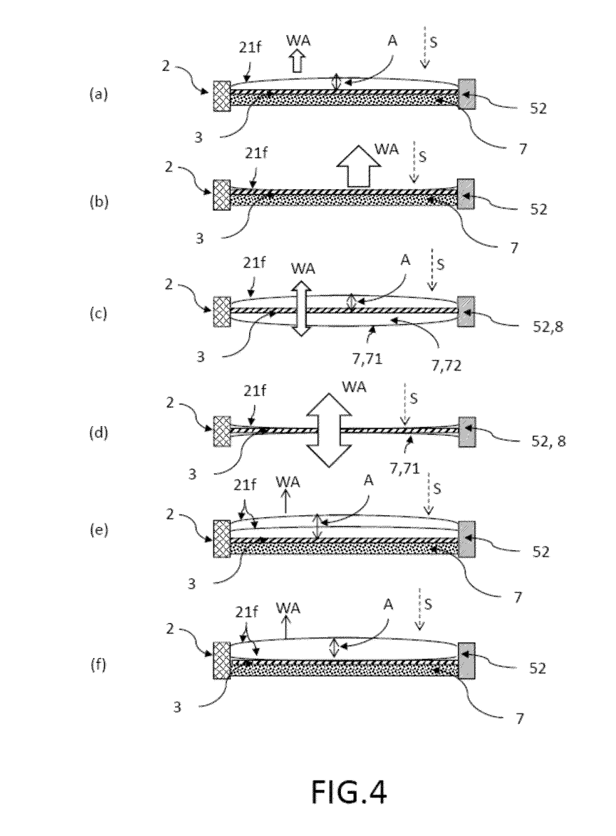

FIG. 4 illustrates several embodiments of the solar collectors 1, each comprising a flexible cover 21f, whereby the embodiments shown under the individual subheadings (a) to (f) largely match those in FIG. 3, although with the difference that the solar collectors from FIG. 4 have a flexible cover for purposes of varying the distance; in this context, also see FIG. 2.

(a) This embodiment corresponds to the solar collector 1 already shown in FIG. 2, with a cover 21f that bulges towards the outside and with non-adjustable thermal insulation 7 at the rear. Here, the heat release WA through the bulging cover 21f is low due to the large mean distance A that has been set.

(b) This embodiment corresponds to the solar collector 1 already shown in FIG. 2, with a cover 21 in contact with the absorber 3 and with non-adjustable thermal insulation 7 at the rear. Here, the heat release WA through the cover 21f that makes contact is at its maximum due to the minimized distance A from the absorber (A=0 when the cover is in contact).

(c) This is another embodiment of a solar collector 1. The side facing the incident sunlight S matches the situation shown in FIG. 4(a). Here, however, the thermal insulation at the rear comprises a rear wall 71, such as a film or plate, and a gas-filled gap 72 between the wall 71 and the rear of the absorber 3. Setting component 8 arranged on the housing 2 were employed to set a large gap 72 between the wall 71 that bulges towards the outside and the rear of the absorber 3. As a result, the heat release WA is low, both through the cover 21f and through the rear (wall) 71. In some embodiments, the setting component 8 can be configured so as to be separate from the setting component 5 and from the device 52 for varying the gas pressure. Here, in contrast, the device 52 is also responsible for setting the width of the gap 72. The device 52 at the rear of the absorber corresponds to the device 52 for causing the cover 21f to bulge on the side facing the incident sunlight S.

(d) This is the embodiment like in FIG. 4(c), whereby now the distances A between the cover 21f and the absorber 3 as well as between the wall 71 and the absorber 3 are minimized (negative pressure). As a result, the heat release WA through the cover 21f as well as through the rear (wall) 71 is at its maximum.

(e) This shows another embodiment of a solar collector 1, with a multiple cover 21f, configured here as a two-part cover 21f. Here, the heat release WA through the two raised covers 21f is even much lower than, for example, in FIG. 4(a), since the two distances A have been set to be large. Here, the thermal insulation 7 at the rear in not adjustable. The heat release through this thermal insulation 7 at the rear depends on its quality.

(f) This embodiment, as already shown in FIG. 4(e), shows the inner cover 21f in contact with to the absorber 3, so that, all in all, the same properties are obtained for the heat release WA as in FIG. 4(a).

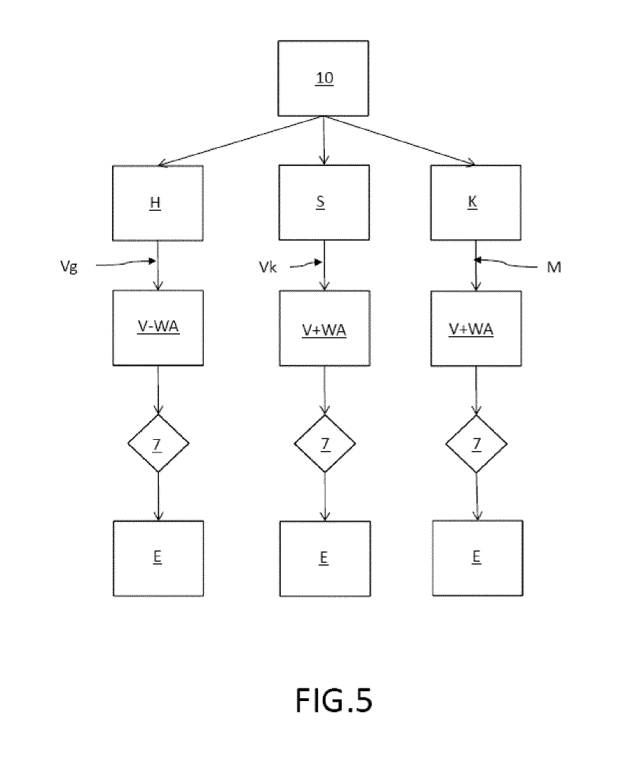

FIG. 5 shows an embodiment of a method for operating a solar collector 1, comprising a control unit 10 for selecting the mode of operation of the solar collector 1. Here, it is possible to choose from among heating operation H (high demand for heat release to the heat-transfer medium 4), stagnation operation S (no heat release to the heat-transfer medium 4 is required, components of the solar collector 1 should not overheat) and cooling operation (the heat-transfer medium 4 should be cooled by releasing heat WA of the solar collector 1 to the environment). Within the scope of the techniques described herein, the person skilled in the art can also define other modes of operation in order to set a specific distance A at least between the cover 21 and the absorber 3, optionally also between the wall 71 at the rear and the absorber 3. With the method described herein, depending on the mode of operation selected, at least the mean distance A between the absorber 3 and the transparent cover 21 is increased Vg in order to decrease V−WA the heat release WA to the environment, or else at least the mean distance A between the absorber 3 and the transparent cover 21 is decreased Vk in order to increase V+WA the heat release WA to the environment. In the case of cooling operation, the distance A between the absorber 3 and the transparent cover 21 is minimized M in order to release heat WA from the housing 2 of the solar collector 1 to the environment. Here, the steps of increasing Vg or decreasing Vk are carried out by appropriately mechanically moving the cover 21 by a mechanical drive 51 or by changing the gas pressure at least between the cover 21f and the absorber 3 by a fan 52. In this context, in order to promote the effect of the higher or lower heat release WA at the front, the extent of the rear thermal insulation 7 consisting of a wall 71 arranged at the rear and a gas-filled gap 72 located between the wall 71 and the rear of the absorber 3 can be appropriately set by changing the gas pressure in the gap 72 using a setting component 8 that is arranged at least partially in the housing, or else by increasing Vg or decreasing Vk the gap 72 between the wall 71 and the rear of the absorber 3 employing a setting component 9 suitable for this purpose.

Alternative embodiments that might be considered by the person skilled in the art within the scope of the embodiments described herein are likewise encompassed by the scope of protection of the the embodiments described herein. In the claims, terms like “one” also include the plural. The reference numerals given in the claims should not be construed as a limitation.

1. (canceled)

2. A solar collector, comprising:
a housing; and
an absorber arranged in the housing to release heat to a heat-transfer medium that flows at least partially through the housing,
at least one transparent cover of the housing to allow incident sunlight to pass through onto the absorber and to modify a heat release to a surrounding environment, the cover is arranged in the housing such that at least a mean distance between the cover and the absorber can be varied in order to adjust the heat release.

3. The solar collector according to claim 2, wherein the cover comprises at least one plastic film or plastic plate, the plastic film or plastic place composed of either a fluoropolymer material or at least one glass pane.

4. The solar collector according to either claim 2, wherein the solar collector comprises a setting component to vary a distance between the absorber and the cover.

5. The solar collector according to claim 4, wherein the solar collector comprises a photovoltaic element to supply the setting component with electricity.

6. The solar collector according to claim 5, wherein the absorber comprises:
the photovoltaic element; and
a device at the rear to transfer heat to the heat-transfer medium, the absorber is configured as a photovoltaic element with a device at the rear for thermal release.

7. The solar collector according to claim 4, wherein the setting component comprises a mechanical drive, whereby the cover is mounted on the housing in such a way that it can be moved relative to the absorber, and the mechanical drive and a mounting of the cover are configured in such a way that the distance between the absorber and the cover can be varied by the mechanical drive.

8. The solar collector according to claim 2, wherein the cover comprises, aside from at least one plastic film, also a readjustment mechanism which is suitable for accommodating thermal material expansions and in which the plastic film is fastened.

9. The solar collector according to claim 4, wherein the cover is an air-tight, mechanically flexible cover connected to the housing, the housing is filled with gas, at least between the cover and the absorber, and in that the setting component comprises a fan for variably selecting the gas pressure in the housing.

10. The solar collector according to claim 2, wherein the heat-transfer medium flows through the absorber, which is made of plastic, ethylene propylene diene monomer (EPDM), or of a coated material, a selectively coated material, or else consists at least partially of a photovoltaic element.

11. The solar collector according to claim 2, wherein the housing comprises a thermal insulation at the rear.

12. The solar collector according to claim 11, wherein the thermal insulation at the rear comprises a thermal insulation material or a wall at the rear comprising a film or plate, and a gas-filled gap between the wall and the rear of the absorber, and wherein, the housing comprises, at least partially, pressure setting component for setting the gas pressure in the gas-filled gap or else gap enlarging component between the wall and the rear of the absorber.

13. A method for operating a solar collector comprising a housing with a transparent cover and an absorber arranged in the housing, in order to release heat to a heat-transfer medium that flows at least partially through the housing, the method comprising:
increasing at least the mean distance between the absorber and the transparent cover in order to decrease the heat release to the environment as needed; and
reducing at least the mean distance between the absorber and the transparent cover in order to increase the heat release to the environment as needed.

14. The method according to claim 13, comprising minimizing the distance between the absorber and the transparent cover in order to release heat from the housing of the solar collector into the environment.

15. The method according to claim 13, wherein increasing or decreasing the distance comprise:
mechanically moving the cover by a mechanical drive; or
changing the gas pressure at least between the cover and the absorber by a fan.

16. The method according to claim 13, comprising:
setting the degree of thermal insulation at the rear, which consists of a wall arranged at the rear, preferably a film or plate, and of a gas-filled gap located between the wall and the rear of the absorber, by changing gas pressure in the gap; or
enlarging or reducing the gap between the wall and the rear of an absorber setting component.
